(19) United States
(12) Patent Application Publication
(10) Pub. No.: US 2023/0112526 A1
(43) Pub. Date: Apr. 13, 2023

(54) METHOD FOR MONITORING ABNORMAL CONDITIONS IN AN ELECTRICAL DISTRIBUTION SYSTEM

(71) Applicant: Astronics Advanced Electronic Systems Corp., Kirkland, WA (US)

(72) Inventors: Fred J. Potter, Trumbauersville, PA (US); Patrick Mills, Bradenton, FL (US); Warren J. Wambsganss, Snoqualmie, WA (US); Massoud Vaziri, Redmond, WA (US)

(73) Assignee: Astronics Advanced Electronic Systems Corp., Kirkland, WA (US)

(21) Appl. No.: 17/943,163

(22) Filed: Sep. 12, 2022

Related U.S. Application Data
(60) Provisional application No. 63/243,138, filed on Sep. 11, 2021.

(51) Int. Cl. G01R 19/25; G01R 19/10; G01R 31/54

(52) U.S. Cl. CPC G01R 19/2513; G01R 19/10; G01R 31/54

(57) ABSTRACT

A method which allows for the quick and accurate detection of faulty operating conditions and bad interconnections between and within devices in an electrical system. The method allows for the detection of arcing in wiring and components, high resistance connections, loose components, and the like. Voltage or current at each end of a conductor, or on each side of a system component, or the current through a component, may be detected and analyzed. A fault or abnormal condition is indicated when the voltage or current exceeds an expected level. Alternatively, resistance may be detected and analyzed, and a fault condition indicated when the resistance exceeds an expected level. Existing detection or computation equipment already associated with the system may be used for the detection and analysis.

### CROSS-REFERENCE TO RELATED APPLICATION

The present disclosure claims the benefit of priority of U.S. Provisional Patent Application No. 63/243,138, filed Sep. 11, 2021, which is herein incorporated by reference in its entirety.

### TECHNICAL FIELD

The field of the invention generally pertains to detection of abnormal electrical conditions.

### BACKGROUND OF THE DISCLOSURE

This disclosure is directed to systems and methods for simply, quickly and accurately detecting the presence of abnormal operating conditions in an electrical power distribution system and what they are caused by. Such abnormal operating conditions may be due to interconnection problems that can occur either between or within the components of a power distribution system. For example, wiring connections may develop high resistances, arcing may occur in the wiring or within the components, etc. Such abnormal operating conditions caused by, e.g., the foregoing interconnection problems, can result in faults and excessive power loss in the system if they are not promptly located and corrected. In accordance with this disclosure, by appropriately monitoring and comparing voltages and currents within the system, such faults may be readily detected so that corrective steps may be taken to avoid damage to the system.

In particular, this disclosure allows for the quick and accurate detection of faulty operating conditions and bad interconnections between and within components of an electrical power distribution system. By way of example, this disclosure allows for detection of arcing in the wiring and components, high resistance connections, and other causes of excessive power loss in a power system. In accordance with this disclosure, simple rules may be used to compare the voltage at each end of a conductor, or on each side of a system component, and/or the current through it, and will declare a fault when the power level exceeds what is expected.

By comparing voltages between system components, and/or from input to output of such components, the methods disclosed herein are simple to implement, work with AC or DC power sources, and at any voltage or current level.

### SUMMARY OF THE DISCLOSURE

This disclosure is made in conjunction with the accompanying Figures, in which:

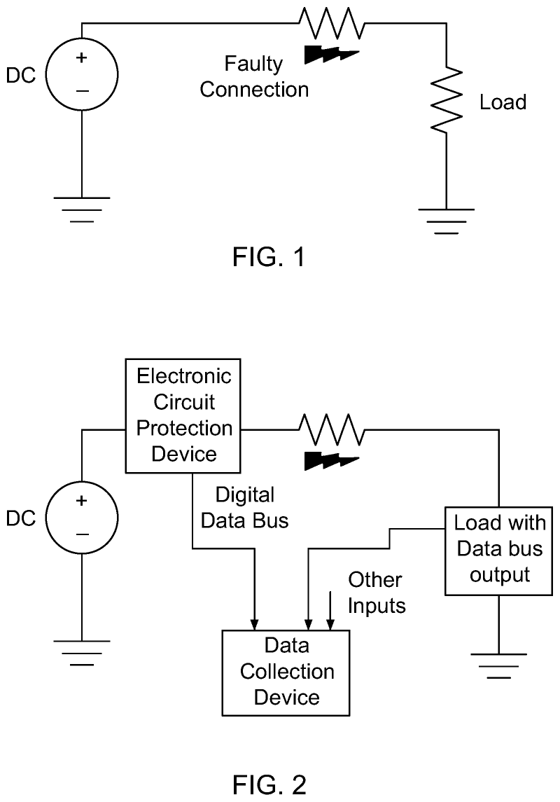

FIG. 1 shows an exemplary faulty interconnection;

FIG. 2 illustrates voltage and current data collection over digital busses; and

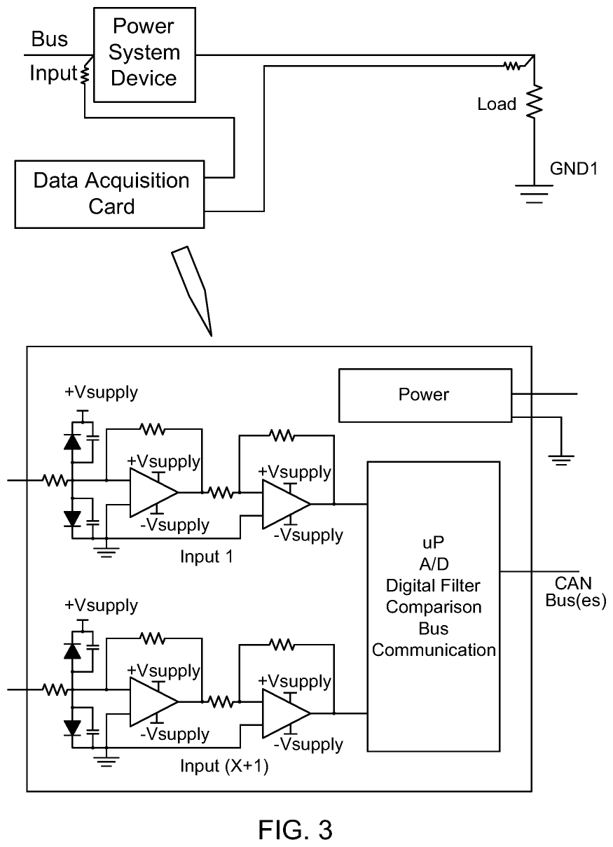

FIG. 3 illustrates voltage and current data collection using a data acquisition card.

Faulty connections in power interconnect wiring and within loads connected to a power distribution system can lead to high resistance, arcing, and unacceptable power losses. In critical applications, such as aircraft power systems where safety concerns are paramount, such faulty connections, if not detected and promptly corrected, can pose significant operational and safety issues.

An illustration of a faulty connection between a voltage source and a load is shown in FIG. 1. As shown, such faulty connection may manifest itself by an undesirable increase in the resistance of the line between the power source and the load. Such higher than desired resistance in the conduction path can be caused in many ways. For example, a loose crimp, a damaged wire, a partially unseated connector, or a screw that has vibrated loose are some examples of common occurrences that can lead to an unexpected higher resistance in the conduction path. Within a load, these same issues apply. In addition, bad soldering and damaged electronic devices may sometimes lead to such faults.

The current consumed in a load indicates a great deal about the health of that load. Too much current or too little current are both events that indicate something is wrong. By way of example, and in accordance with this disclosure, circuit breaker trip events may be analyzed to identify the likely failure mode that has caused the trip to occur. For example, an instantaneous circuit breaker trip event typically occurs when a current spike is generated that exceeds 10 times the breaker's rating. This type of event, which indicates that a very high current was interrupted, is most likely caused by a wiring fault. On the other hand, a circuit breaker over-current trip event occurs when current causes the breaker to trip after an extended period of over-current. When such over-current trip event occurs, it is most likely indicative of a fault within the load, rather than a wiring fault.

As shown in FIG. 2, in a typical power distribution system, voltage and current data needed to analyze and identify occurrences of any of the foregoing events, may be gathered by a data collection device as a part of the normal operation of the power distribution system, and such data may be made available on digital data busses. If such data collection device is not already present in the power distribution system, it can be readily added by workers of ordinary skill in the art.

In accordance with this disclosure, the voltage and current data can be collected and analyzed by a computational device. The computation device may oftentimes already be present in the system and used for other purposes, or it may be readily added, if need be, by workers of ordinary skill in the art.

In accordance with this disclosure, to aid in identifying abnormal operating conditions, such data is analyzed in real time using a set of simple rules that may be implemented in software. The rules are designed to promptly identify and locate power losses that should not exist when the system is working correctly.

By way of example, actual current usage may be compared to pre-set maximum and minimum current levels. Such maximum and minimum currents can also be adjusted based on prior stored data (compare with average), or can vary based on operational profiles. As another example, a rule for finding high resistance wire connections or series arc faults may be to set to identify a delta voltage limit between the output of one device and the input of another. Such voltage limit could be absolute, e.g., based on regulatory requirements for wire voltage drop (e.g., max 2% drop in voltage), or set by the expected wire resistance and the measured current.

As yet another example, a rule may be defined to find a faulty device in the power supply system by setting and monitoring current limits for the minimum and maximum current draw of a component when it is powered, Such current limits may be either absolute limits or based on current flow averaged over time.

Another exemplary rule may be used to find the likely failure mode that causes an electronic protection device to trip. In this case, such rule may differentiate between an over-current trip event (current causing the breaker to trip after an extended period of over-current) and an instantaneous trip event (e.g., caused by a current spike exceeding 10 times the breaker's rating). Overcurrent trips would likely indicate a device fault, whereas an instant trip would be likely be indicative of a wiring fault.

An alternative voltage or current measurement method that may be used when voltage and current data is not available on a data bus is shown in FIG. 3. In this example, a data acquisition card may be added to the system. Alternatively, other analog data acquisition devices that may already be present in the system can be used. The data acquisition card is used to acquire and digitize analog line data, making the digital data available for use as above, to locate and analyze the causes of faulty connections.

What is claimed is:

1. A method of monitoring for an abnormal electrical condition in a system, comprising:
obtaining voltage or current information at a plurality of points in said system;
determining a power loss between two of said plurality of points;
identifying a determined power loss exceeding a predetermined power loss threshold as an indication of an abnormal electrical condition.

2. The method of claim 1, wherein the step of determining a power loss includes a step of determining a voltage difference between an output of a first device in the system and an input of a second device in the system, and further indicating the abnormal electrical condition when the determined voltage difference exceeds a predetermined voltage difference based on an expected resistance and an expected current between said first and second devices.

3. The method of claim 2, wherein the predetermined voltage difference is set as an absolute voltage difference.

4. The method of claim 2, wherein the predetermined voltage difference is set based on the obtained current information between said first and second devices.

5. The method of claim 1, wherein the step of determining a power loss includes a step of determining a voltage difference between an input of a first device in the system and an output of the first device in the system, and further indicating the abnormal electrical condition when the determined voltage difference exceeds a predetermined voltage difference based on an expected current at said input and at said output.

6. The method of claim 5, wherein the predetermined voltage difference is set as an absolute voltage difference.

7. The method of claim 5, wherein the predetermined voltage difference is set based on the obtained current information between said first and second devices.

8. The method of claim 1, wherein the step of determining a power loss includes a step of determining a resistance between an output of a first device in the system and an input of a second device in the system, and further indicating the abnormal electrical condition when the determined resistance exceeds a predetermined resistance based on an expected resistance between said first and second devices.

9. The method of claim 8, wherein the predetermined resistance difference is set as an absolute resistance difference.

10. The method of claim 8, wherein the predetermined resistance difference is set based on the obtained current information.

11. The method of claim 1, wherein the step of determining a power loss includes a step of determining a resistance difference between an input of a first device in the system and an output of the first device in the system, and further indicating the abnormal electrical condition when the determined resistance difference exceeds a predetermined resistance difference based on an expected current at said input and at said output.

12. The method of claim 11, wherein the predetermined resistance difference is set as an absolute resistance difference.

13. The method of claim 11, wherein the predetermined resistance difference is set based on the obtained current information at said input or at said output.

14. The method of claim 1, wherein the obtaining step is performed using existing data collection equipment associated with the system.

15. The method of claim 1, wherein the determining or identifying steps are performed using existing computational devices associated with the system.

16. The method of claim 2, wherein the obtaining step is performed using existing data collection equipment associated with the system and the determining or identifying steps are performed using existing computational devices associated with the system.

17. The method of claim 5, wherein the obtaining step is performed using existing data collection equipment associated with the system and the determining or identifying steps are performed using existing computational devices associated with the system.

18. The method of claim 8, wherein the obtaining step is performed using existing data collection equipment associated with the system and the determining or identifying steps are performed using existing computational devices associated with the system.

19. The method of claim 11, wherein the obtaining step is performed using existing data collection equipment associated with the system and the determining or identifying steps are performed using existing computational devices associated with the system.

20. The method of claim 1, wherein the abnormal electrical condition includes arcing in wiring, a loose crimp, a damaged wire, a partially unseated connector, or a loose screw.
